(19) United States
(12) Patent Application Publication
(10) Pub. No.: US 2025/0385191 A1
(43) Pub. Date: Dec. 18, 2025

(54) SEMICONDUCTOR PACKAGE DEVICE AND SEMICONDUCTOR WIRING SUBSTRATE THEREOF

(71) Applicants: GLOBAL UNICHIP CORPORATION, HSINCHU CITY (TW); TAIWAN SEMICONDUCTOR MANUFACTURING COMPANY, LTD., Hsinchu (TW)

(72) Inventors: Wei-Chiao WANG, HSINCHU CITY (TW); Sheng-Fan YANG, HSINCHU CITY (TW); Yi-Tzeng LIN, HSINCHU CITY (TW); Yuan-Hung LIN, HSINCHU CITY (TW); Li-Ya TSENG, HSINCHU CITY (TW); Ya-Ting HSIEH, HSINCHU CITY (TW)

(21) Appl. No.: 18/945,571

(22) Filed: Nov. 13, 2024

(30) Foreign Application Priority Data
Jun. 17, 2024 (TW) 113122350

(51) Int. Cl. H01L 23/538; H01L 25/065

(52) U.S. Cl. CPC H01L 23/5386; H01L 23/5383; H01L 25/0655

(57) ABSTRACT

A semiconductor wiring substrate comprises a first circuit layer, a second circuit layer, a plurality of first signal traces and a plurality of second signal traces. The second circuit layer is arranged in parallel with the first circuit layer. A part of the first signal traces is arranged on the first circuit layer, and another part of the first signal traces is arranged on the second circuit layer. A part of the second signal traces is arranged on the first circuit layer, and another part of the second signal traces is arranged on the second circuit layer. The part of the first signal traces and the part of the second signal traces are arranged on the first circuit layer along a first direction, another part of the first signal traces and another part of the second signal traces are arranged on the second circuit layer along the first direction.

### RELATED APPLICATIONS

This application claims the priority benefit of Taiwan Application Serial Number 113122350, filed Jun. 17, 2024, which is herein incorporated by reference.

### BACKGROUND

### Field of Invention

The present disclosure relates to a semiconductor wiring substrate, and in particular to a semiconductor wiring substrate for a semiconductor package device.

### Description of Related Art

As the requirements for high performance computing grow, the demand for high bandwidth memory also increases, and thus the requirements for wiring flexibility and signal integrity also increase. Therefore, it is necessary to improve current design to meet the requirements.

### SUMMARY

An aspect of present disclosure relates to a semiconductor wiring substrate for signal transmission between a first chip and a second chip. The semiconductor wiring substrate comprises a first circuit layer, a second circuit layer, a plurality of first signal traces and a plurality of second signal traces. The second circuit layer is arranged in parallel with the first circuit layer. The first signal traces are configured to transmit a first byte signal, a part of the first signal traces is arranged on the first circuit layer, and another part of the first signal traces is arranged on the second circuit layer. The second signal traces are configured to transmit a second byte signal, a part of the second signal traces is arranged on the first circuit layer, and another part of the second signal traces is arranged on the second circuit layer. The part of the first signal traces and the part of the second signal traces are arranged on the first circuit layer along a first direction, another part of the first signal traces and another part of the second signal traces are arranged on the second circuit layer along the first direction.

Another aspect of present disclosure relates to a semiconductor package device. The semiconductor package device comprises a first chip, a second chip, a package substrate and an interposer. The second chip is configured to perform a transmission of at least one signal with the first chip by at least one channel. The interposer comprises a semiconductor wiring substrate, a first surface and a second surface, wherein the second chip is electrically coupled to the first chip via the interposer, the first surface and the second surface are opposite to each other, the first chip and the second chip are electrically connected to the first surface, and the package substrate is electrically connected to the second surface. The semiconductor wiring substrate comprises a first circuit layer, a second circuit layer, a plurality of first signal traces and a plurality of second signal traces. The second circuit layer is arranged in parallel with the first circuit layer. The first signal traces are configured to transmit a first byte signal, a part of the first signal traces is arranged on the first circuit layer, and another part of the first signal traces is arranged on the second circuit layer. The second signal traces are configured to transmit a second byte signal, a part of the second signal traces is arranged on the first circuit layer, and another part of the second signal traces is arranged on the second circuit layer. The part of the first signal traces and the part of the second signal traces are arranged on the first circuit layer along a first direction, another part of the first signal traces and another part of the second signal traces are arranged on the second circuit layer along the first direction.

The present disclosure provides a semiconductor package device and a semiconductor wiring substrate thereof. The circuit layout of the semiconductor wiring substrate is that a part of the first signal traces and a part of the second signal traces are arranged on the first circuit layer, another part of the first signal traces and another part of the second signal traces are arranged on the second circuit layer adjacent to the first circuit layer, a part of the third signal traces and a part of the fourth signal traces are arranged on the third circuit layer, and another part of the third signal traces and another part of the fourth signal traces are arranged on the fourth circuit layer adjacent to the third circuit layer, so that the first byte signal and the second byte signal can be transmitted on the adjacent first circuit layer and second circuit layer, and the third byte signal and the fourth byte signal can be transmitted on the adjacent third circuit layer and fourth circuit layer, resulting in reducing crosstalk between the first signal trace, the second signal trace, the third signal trace and the fourth signal trace in semiconductor wiring substrate.

### BRIEF DESCRIPTION OF THE DRAWINGS

The disclosure can be more fully understood by reading the following detailed description of the embodiment, with reference made to the accompanying drawings as follows:

FIG. 1 is a partial schematic diagram of a semiconductor wiring substrate, in accordance with some embodiments of the present disclosure.

FIG. 2 is a schematic diagram of overall structure of a semiconductor wiring substrate, in accordance with some embodiments of the present disclosure.

FIG. 3A is a schematic diagram of circuit layout of one embodiment of the first signal traces, the second signal traces, the third signal traces and the fourth signal traces of the semiconductor wiring substrate in FIG. 2.

FIG. 3B is a schematic diagram of circuit layout of another embodiment of the first signal trace, the second signal trace, the third signal trace and the fourth signal trace of the semiconductor wiring substrate in FIG. 2.

FIGS. 4A-4E are schematic diagrams of the crosstalk on the signal trace in the dotted box of FIGS. 3A-3B under various operating conditions.

FIG. 5 is a partial schematic diagram of a semiconductor package device, in accordance with some embodiments of the present disclosure.

FIG. 6 is eye diagrams of signal waveforms at a relatively low transfer rate for a semiconductor package device using practical application technology and the semiconductor package device using the configuration of the present disclosure.

FIG. 7 is eye diagrams of signal waveforms at a medium transfer rate for the semiconductor package device using practical application technology and the semiconductor package device using the configuration of the present disclosure.

FIG. 8 is eye diagrams of signal waveforms at a relatively high transfer rate for the semiconductor package device using practical application technology and the semiconductor package device using the configuration of the present disclosure.

### DETAILED DESCRIPTION

The embodiments are described in detail below with reference to the appended drawings to better understand the aspects of the present disclosure. However, the provided embodiments are not intended to limit the scope of the disclosure, and the description of the structural operation is not intended to limit the order in which they are performed. Any device that has been recombined by components and produces an equivalent function is within the scope covered by the disclosure.

The terms used in the entire specification and the scope of the patent application, unless otherwise specified, generally have the ordinary meaning of each term used in the field, the content disclosed herein, and the particular content.

As used herein, “coupled” and “connected” can be used to indicate that two or more elements physical or electrical contact with each other directly or indirectly, and can also be used to indicate that two or more elements cooperate or interact with each other.

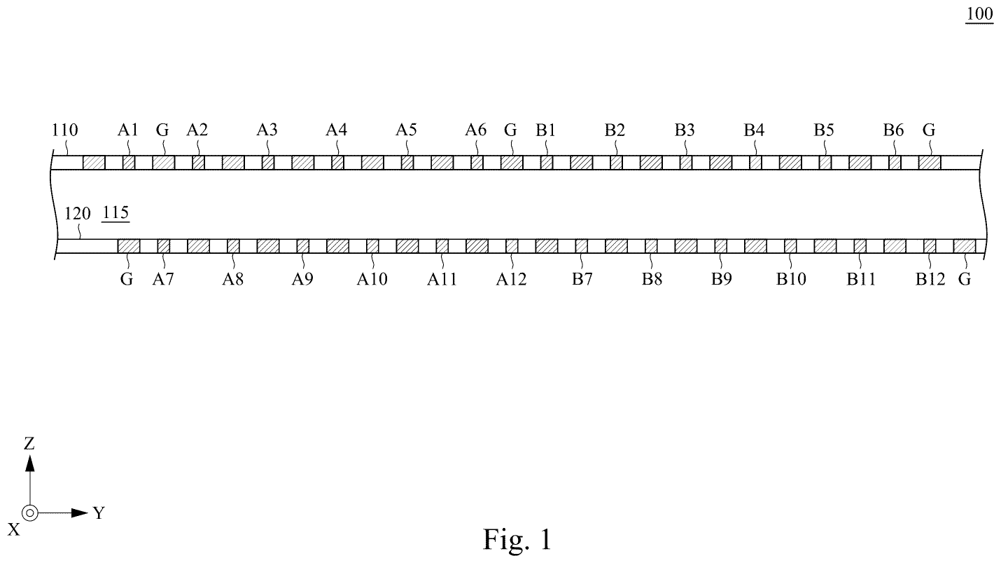

Reference is made to FIG. 1. FIG. 1 is a partial schematic diagram of a semiconductor wiring substrate 100, in accordance with some embodiments of the present disclosure. As shown in FIG. 1, the semiconductor wiring substrate 100 comprises a first circuit layer 110, a second circuit layer 120, a plurality of first signal traces A1˜A12, a plurality of second signal traces B1˜B12 and a first dielectric layer 115.

The second circuit layer 120 is arranged in parallel with the first circuit layer 110 (e.g., the second circuit layer 120 is arranged parallel below the first circuit layer 110).

In one embodiment, the first signal traces A1˜A12 are configured to transmit a first byte signal A. For example, the first byte signal A includes 8 data bits, and can comprise additional control bits in addition to the 8 data bits to realize the control function (e.g., data debugging, data parity check, clock control) of data transmission in actual application scenarios. For example, the additional control bits can be dbi bits, ecc bits (for data debugging), dpar bits (for data parity check), rant bits, WDQS bits, RDQS bits and sev bits, but the present disclosure does not limit herein.

In this embodiment, the first byte signal A includes 8 data bits and 4 control bits. The first signal traces A1˜A8 are configured to transmit the 8 data bits of the first byte signal A, and the first signal traces A9 to A12 are configured to transmit the 4 control bits of the first byte signal A. In other words, all bits of the first byte signal A are transmitted by the first signal traces A1˜A12, but the present disclosure does not limit the number herein. In another embodiment, the first byte signal A can only include 8 data bits and be transmitted by the 8 first signal traces. Or in yet another embodiment, the first byte signal A can include 8 data bits+K control bits and be transmitted by 8+K first signal traces, where K is any positive integer.

Similarly, the second signal traces B1˜B12 are configured to transmit the second byte signal B. For example, the second byte signal B also includes 8 data bits and additional control bits. For example, the additional control bits can be dbi bits, ecc bits (for data debugging), dpar bits (for data parity check), rdnt bits, WDQS bits, RDQS bits and sev bits, but the present disclosure does not limit thereto.

In this embodiment, the second byte signal B also includes 8 data bits and 4 control bits. The second signal traces B1˜B8 are configured to transmit the 8 data bits of the second byte signal B, and the second signal traces B9˜B12 are configured to transmit the 4 control bits of the second byte signal B. In other words, all bits of the second byte signal B are transmitted by the second signal traces B1˜B12, but the present disclosure does not limit the number herein. In one embodiment, the second byte signal B can also include 8 data bits+L control bits and be transmitted by 8+L second signal traces, where L is zero or any positive integer.

In general situation, signal traces configured to transmit the same byte signal are often distributed on the same circuit layer. Two sets of signal traces on two adjacent circuit layers can be configured to transmit two different byte signals. Since the two different byte signals usually have different voltage/current characteristics, the two sets of signal traces on the two adjacent circuit layers can be likely to interfere with each other when transmitting two different byte signals respectively, resulting in signal noise, that is, crosstalk.

In this embodiment, as shown in the first signal traces A1˜A12 configured to transmit the first byte signal A of FIG. 1, where a part of the first signal traces A1˜A12 (such as the first signal traces A1˜A6) is arranged on the first circuit layer 110, where another part of the first signal traces A1˜A12 (such as the first signal traces A7˜A12) is arranged on the second circuit layer 120, that is, the first signal traces A1˜A6 and the first signal traces A7˜A12 are respectively arranged on the first circuit layer 110 and the second circuit layer 120, which are different. From the perspective of FIG. 1, the first signal traces A1˜A6 on the first circuit layer 110 and the first signal traces A7˜A12 on the second circuit layer 120 are arranged in a zigzag shape along a direction Y. In other words, projections of the first signal traces A1˜A6 and the first signal traces A7˜A12 from different circuit layers along a direction Z are not overlapped, and have different horizontal positions in the direction Y.

Similarly, in this embodiment, as shown in the second signal traces B1˜B12 configured to transmit the second byte signal B of FIG. 1, where a part of the second signal traces B1˜B12 (such as the second signal traces B1˜B6) is arranged on the first circuit layer 110, where another part of the second signal traces B1˜B12 (such as the second signal traces B7˜B12) is arranged on the second circuit layer 120, that is, the second signal traces B1˜B6 and the second signal traces B7˜B12 are respectively arranged on the first circuit layer 110 and the second circuit layer 120, which are different. From the perspective of FIG. 1, the second signal traces B1˜B6 on the first circuit layer 110 and the second signal traces B7˜B12 on the second circuit layer 120 are arranged in the zigzag shape along the direction Y. In other words, projections of the second signal traces B1˜B6 and the second signal traces B7˜B12 from different circuit layers along the direction Z are not overlapped, and have different horizontal positions in the direction Y.

Therefore, as shown in FIG. 1, a part of the first signal traces A1˜A12 (such as the first signal traces A1˜A6) and a part of the second signal traces B1˜B12 (such as the second signal traces B1˜B6) are arranged on the first circuit layer 110 along the direction Y (i.e., the direction parallel to the first circuit layer 110), another part of the first signal traces A1˜A12 (such as the first signal traces A7˜A12) and another part of the second signal traces B1˜B12 (such as the second signal traces B7˜B12) are arranged on the second circuit layer 120 along the direction Y (i.e., the direction parallel to the second circuit layer 120).

In the embodiment of FIG. 1, the first signal traces A1˜A12 transmitting the first byte signal A are respectively arranged on two adjacent circuit layers and are concentrated on the left side shown in FIG. 1. Since the same first byte signal A can have similar voltage/current characteristics, crosstalk among the first signal traces A1˜A12 can be reduced when the first signal traces A1˜A12 transmit the same first byte signal A. On the other hand, the second signal traces B1˜B12 transmitting the second byte signal B are respectively arranged on two adjacent circuit layers and are concentrated on the right side shown in FIG. 1. Since the same second byte signal B can also have similar voltage/current characteristics, crosstalk among the second signal traces B1˜B12 can also be reduced when the second signal traces B1˜B12 transmit the same second byte signal B. Furthermore, the first signal traces A1˜A12 and the second signal traces B1˜B12 are respectively arranged on the left and right sides of the semiconductor wiring substrate 100, and thus the crosstalk between the first signal traces A1˜A12 and the second signal traces B1˜B12 can also be reduced.

In the embodiment of FIG. 1, in addition to the first signal traces A1˜A6 and the second signal traces B1˜B6, a plurality of ground traces G are arranged on the first circuit layer 110. Each of the ground traces G is respectively arranged between two adjacent signal traces. For example, a ground trace G is arranged between the first signal trace A1 and A2; a ground trace G is arranged between the first signal trace A6 and the second signal trace B1; a ground trace G is arranged between the second signal traces B1 and B2.

Similarly, in the embodiment of FIG. 1, in addition to the first signal traces A7˜A12 and the second signal traces B7˜B12, a plurality of ground traces G are also arranged on the second circuit layer 120. Each of the ground traces G is respectively arranged between two adjacent signal traces. For example, a ground trace G is arranged between the first signals traces A7 and A8; a ground trace G is arranged between the first signal trace A12 and the second signal trace B7; a ground trace G is arranged between the second signal traces B7 and B8.

In the embodiment of FIG. 1, the signal traces (e.g., the first signal traces A1˜A6, the second signal traces B1˜B6) and the ground traces G on the first circuit layer 110 are alternately arranged on the first line layer 110 along the direction Y. For example, the first signal trace A1, the ground trace G and the first signal trace A2 are sequentially arranged on the first circuit layer 110 along the direction Y (i.e., the direction parallel to the first circuit layer 110), the first signal trace A6, the ground trace G and the second signal trace B1 are sequentially arranged on the first circuit layer 110 along the direction Y, and the second signal trace B1, the ground trace G and the second signal trace B2 are sequentially arranged on the first circuit layer 110 along the direction Y.

Similarly, in the embodiment of FIG. 1, the signal traces (e.g., the first signal traces A7˜A12, the second signal traces B7˜B12) and the ground traces G on the second circuit layer 120 are alternately arranged on the second circuit layer 120 along the direction Y. For example, the first signal trace A7, the ground trace G and the first signal trace A8 are sequentially arranged on the second circuit layer 120 along the direction Y (i.e., the direction parallel to the second circuit layer 120), the first signal trace A12, the ground trace G and the second signal trace B7 are sequentially arranged on the second circuit layer 120 along the direction Y, and the second signal trace B7, the ground trace G and the second signal trace B8 are sequentially arranged on the second circuit layer 120 along the direction Y.

It is worth noting that a ground width gw of each of the ground traces G, in the embodiment of FIG. 1, is greater than or equal to a signal width sw of each of the first signal traces A1˜A12 or each of the second signal traces B1˜B12, the signal width sw of each of the first signal traces A1˜A12 and each of the second signal traces B1˜B12 is similar or the same.

As such, by the above layout of FIG. 1, the ground trace G can be configured to shield signal crosstalk among the signal traces on the same circuit layer. That is, the ground trace G shields the signal crosstalk among the first signal traces A1˜A6 and the second signal traces B1˜B6 of the first circuit layer 110, and the signal crosstalk among the first signal traces A7˜A12 and the second signal traces B7˜B12 of the second circuit layer 120.

Generally speaking, when the adjacent signal traces transmit the same byte signal, the crosstalk between the signal traces is smaller. If the adjacent signal traces respectively transmit different byte signals, the crosstalk between the signal traces is significant. As shown in the layout of FIG. 1, for the first signal trace A2 on the first circuit layer 110, the signal traces adjacent to the first signal trace A2 comprise the first signal traces A1, A3 on the first circuit layer 110 (a ground trace G is arranged between the first signal traces A1 (or A3) and the first signal trace A2 to shield the signal crosstalk), and the first signal traces A7, A8 on the second circuit layer 120. The unshielded first signal traces A7, A8 adjacent to the first signal trace A2 are configured to transmit the same byte signal, and thus the crosstalk between the first signal traces A7 (or A8) and the first signal trace A2 is smaller.

Furthermore, in the embodiment of FIG. 1, position where the signal crosstalk is likely to occur is at junction of different signal traces. For example, for the first signal trace A12 on the second circuit layer 120, the signal traces adjacent to the first signal trace A12 comprise the first signal trace A6 and the second signal trace B1 on the first circuit layer 110, and the first signal trace A11 and the second signal trace B7 on the second circuit layer 120 (a ground trace G is arranged between the first signal trace A11, the second signal trace B7 and the first signal trace A12 to shield the signal crosstalk). In the layout of FIG. 1, the unshielded first signal trace A6 adjacent to the first signal trace A12 is configured to transmit the same byte signal, and thus the crosstalk between the first signal trace A6 and A12 is smaller. That is to say, other signal traces arranged in a diagonal direction (i.e., the direction between the first signal trace A12 and the first signal trace A6, the direction between the first signal trace A12 and the second signal trace B1, etc.) relative to one of the first signal traces A1˜A12 (e.g., the first signal trace A12) comprise another first signal trace (e.g., the first signal trace A6) transmitting the same byte signal, rather than the signal traces transmitting different byte signals in two diagonal directions.

Similarly, for the second signal trace B1 on the first circuit layer 110, the signal traces adjacent to the second signal trace B1 comprise the first signal trace A6 and the second signal trace B2 on the first circuit layer 110 (a ground trace G is arranged between the first signal trace A6, the second signal trace B2 and the second signal trace B1 to shield the signal crosstalk), and the first signal trace A12 and the second signal trace B7 on the second circuit layer 120. In the layout of FIG. 1, the unshielded second signal trace B7 adjacent to the second signal trace B1 is configured to transmit the same byte signal, and thus the crosstalk between the second signal trace B7 and B1 is smaller. That is to say, in FIG. 1, other signal traces arranged in the diagonal direction (i.e., the direction between the second signal trace B1 and the first signal trace A12, the direction between the second signal trace B1 and the second signal trace B7, etc.) relative to one of the second signal traces B1˜B12 (e.g., the second signal trace B1) comprise another second signal trace (e.g., the second signal trace B7) transmitting the same byte signal, rather than the signal traces transmitting different byte signals in two diagonal directions.

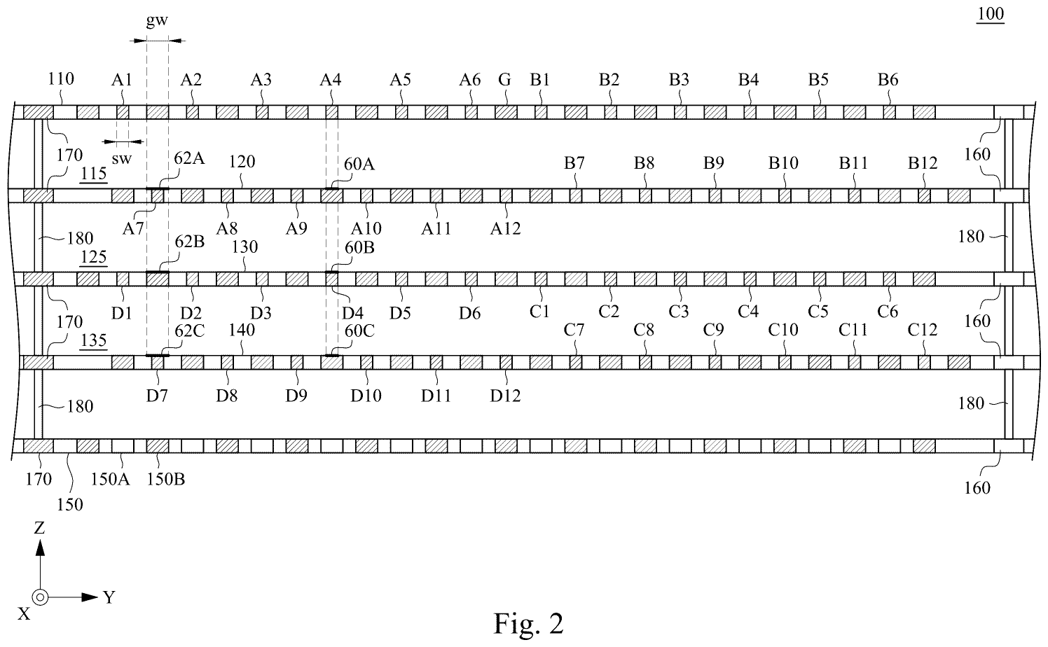

It should be understood that number of circuit layers of the semiconductor wiring substrate 100 is not limited to two, and number of dielectric layers of the semiconductor wiring substrate 100 is not limited to one. Therefore, regarding overall structure of the semiconductor wiring substrate 100, please also refer to FIG. 2.

FIG. 2 is a schematic diagram of the overall structure of a semiconductor wiring substrate 100, in accordance with some embodiments of the present disclosure. As shown in FIG. 2, the semiconductor wiring substrate 100 further comprises a third circuit layer 130, a fourth circuit layer 140, third signal traces C1˜C12, fourth signal traces D1˜D12, a second dielectric layer 125 and a third dielectric layer 135.

The third circuit layer 130 is arranged in parallel with the second circuit layer 120 (e.g., the third circuit layer 130 is arranged parallel below the second circuit layer 120), and the fourth circuit layer 140 is arranged in parallel with the third circuit layer 130 (e.g., the fourth circuit layer 140 is arranged parallel below the third circuit layer 130).

In one embodiment, the third signal traces C1˜C12 are configured to transmit the third byte signal C. For example, the third byte signal C includes 8 data bits. In the actual application scenarios, the third byte signal C can contain additional 4 control bits in addition to the 8 data bits to realize control function of data transmission (e.g., the data debugging, the data parity check, the clock control).

Similarly, the fourth signal traces D1-D12 are configured to transmit the fourth byte signal D. For example, the fourth byte signal D also comprises 8 data bits and additional 4 control bits.

In this embodiment, as shown in the third signal traces C1˜C12 configured to transmit the third byte signal C of FIG. 2, where a part of the third signal traces C1˜C12 (such as the third signal traces C1˜C6) is arranged on the third circuit layers 130, where another part of the third signal traces C1˜C12 (such as the third signal traces C7˜C12) is arranged on the fourth circuit layer 140, that is, the third signal traces C1˜C6 and the third signal traces C7˜C12 are respectively arranged on the third circuit layer 130 and the fourth circuit layer 140, which are different. From the perspective of FIG. 2, the third signal traces C1˜C6 on the third circuit layer 130 and the third signal traces C7˜C12 on the fourth circuit layer 140 are arranged in the zigzag shape along the direction Y. In other words, projections of the third signal traces C1˜C6 and the third signal traces C7˜C12 from different circuit layers along the direction Z are not overlapped, and have different horizontal positions in the direction Y.

Similarly, in this embodiment, as shown in the fourth signal traces D1˜D12 configured to transmit the fourth byte signal D of FIG. 2, where a part of the fourth signal traces D1˜D12 (such as the fourth signal traces D1˜D6) is arranged on the third circuit layer 130, where another part of the fourth signal traces D1˜D12 (such as the fourth signal traces D7˜D12) is arranged on the fourth circuit layer 140, that is, the fourth signal traces D1˜D6 and the fourth signal traces D7˜D12 are respectively arranged on the third circuit layer 130 and fourth circuit layer 140, which are different. From the perspective of FIG. 2, the fourth signal traces D1˜D6 on the third circuit layer 130 and the fourth signal traces D7˜D12 on the fourth circuit layer 140 are arranged in the zigzag shape along the direction Y. In other words, projections of the fourth signal traces D1˜D6 and the fourth signal traces D7˜D12 from different circuit layers along the direction Z are not overlapped, and have different horizontal positions in the direction Y.

Therefore, as shown in FIG. 2, a part of the third signal traces C1˜C12 (such as the third signal traces C1˜C6) and a part of the fourth signal traces D1˜D12 (such as the fourth signal traces D1˜D6) are arranged on the third circuit layer 130 along the direction Y (i.e., the direction parallel to the third circuit layer 130), another part of the third signal traces C1˜C12 (such as the third signal traces C7˜C12) and another part of the fourth signal traces D1˜D12 (such as the fourth signal traces D7˜D12) are arranged on the fourth circuit layer 140 along the direction Y (i.e., the direction parallel to the fourth circuit layer 140).

In the embodiment of FIG. 2, the third signal traces C1˜C12 transmitting the third byte signal C are respectively arranged on two adjacent circuit layers and are concentrated on the right side shown in FIG. 2. Since the same third byte signal C can have similar voltage/current characteristics, crosstalk among the third signal traces C1˜C12 can be reduced when the third signal traces C1˜C12 transmit the same third byte signal C. On the other hand, the fourth signal traces D1˜D12 transmitting the fourth byte signal D are respectively arranged on two adjacent circuit layers and are concentrated on the left side shown in FIG. 2. Since the same fourth byte signal D can also have similar voltage/current characteristics, crosstalk among the fourth signal traces D1˜D12 can also be reduced when the fourth signal traces D1˜D12 transmit the same fourth byte signal D. Furthermore, the fourth signal traces D1˜D12 and the third signal traces C1˜C12 are respectively arranged on the left and right sides of the semiconductor wiring substrate 100, and thus the crosstalk between the fourth signal traces D1˜D12 and the third signal traces C1˜C12 can also be reduced.

In the embodiment of FIG. 2, in addition to the third signal traces C1˜C6 and the fourth signal traces D1˜D6, a plurality of ground traces G are also arranged on the third circuit layer 130. Each of the ground traces G is respectively arranged between two adjacent signal traces. For example, a ground trace G is arranged between the fourth signal trace D5 and D6; a ground trace G is arranged between the fourth signal trace D6 and the third signal trace C1; a ground trace G is arranged between the third signal trace C1 and C2.

Similarly, in the embodiment of FIG. 2, in addition to the third signal traces C7˜C12 and the fourth signal traces D7˜D12, a plurality of grounds are also arranged on the fourth circuit layer 140. Each of the ground traces G is respectively arranged between two adjacent signal traces. For example, a ground trace G is arranged between the fourth signals traces D11 and D12; a ground trace G is arranged between the fourth signal trace D12 and the third signal trace C7; a ground trace G is arranged between the third signal trace C7 and C8.

In the embodiment of FIG. 2, the signal traces (e.g., the third signal traces C1˜C6, the fourth signal traces D1˜D6) and the ground traces G on the third circuit layer 130 are alternately arranged on the third circuit layer 130 along the direction Y (i.e., the direction parallel to the third circuit layer 130). For example, the fourth signal trace D5, the ground trace G and the fourth signal trace D6 are sequentially arranged on the third circuit layer 130 along the direction Y, the fourth signal trace D6, the ground trace G and the third signal trace C1 are sequentially arranged on the third circuit layer 130 along the direction Y, and the third signal trace C1, the ground trace G and the third signal trace C2 are sequentially arranged on the third circuit layer 130 along the direction Y.

Similarly, in the embodiment of FIG. 2, the signal traces (e.g., the third signal traces C7˜C12, the fourth signal traces D7˜D12) and the ground traces G on the fourth circuit layer 140 are alternately arranged on the fourth circuit layer 140 along the direction Y (i.e., the direction parallel to the fourth circuit layer 140). For example, the fourth signal trace D11, the ground trace G and the fourth signal trace D12 are sequentially arranged on the fourth circuit layer 140 along the direction Y, the fourth signal trace D12, the ground trace G and the third signal trace C7 are sequentially arranged on the fourth circuit layer 140 along the direction Y, the third signal trace C7, the ground trace G and the third signal trace C8 are sequentially arranged on the fourth circuit layer 140 along the direction Y.

As such, by the above layout of FIG. 2, the ground trace G can be configured to shield signal crosstalk among the signal traces on the same circuit layer. That is, the ground trace G shields the signal crosstalk between the third signal traces C1˜C6 and the fourth signal traces D1˜D6 of the third circuit layer 130, and the signal crosstalk between the third signal traces C7˜C12 and the fourth signal traces D7˜D12 of the fourth circuit layer 140.

In addition, in the embodiment of FIG. 2, position where the signal crosstalk is likely to occur is at junction of different signal traces. For example, for the third signal trace C1 on the third circuit layer 130, the signal traces adjacent to the third signal trace C1 comprise the first signal trace A12 and the second signal trace B7 on the second circuit layer 120, the fourth signal trace D6 and the third signal trace C2 on the third circuit layer 130 (a ground trace G is arranged between the fourth signal trace D6, the third signal trace C2 and the third signal trace C1 to shield the signal crosstalk), and the fourth signal trace D12 and the third signal trace C7 on the fourth circuit layer 140. In the layout of FIG. 2, the unshielded third signal trace C7 adjacent to the third signal trace C1 is configured to transmit the same byte signal, and thus the crosstalk between the third signal trace C7 and C1 is smaller. That is to say, other signal traces arranged in the diagonal direction (i.e., the direction between the third signal trace C1 and the first signal trace A12, the direction between the third signal trace C1 and the second signal trace B7, the direction between the third signal trace C1 and the third signal trace C7, and the direction between the third signal trace C1 and the fourth signal trace D12) relative to one of the third signal traces C1˜C12 (e.g., the third signal trace C1) comprise another third signal trace (e.g., the third signal trace C7) transmitting the same byte signal, rather than the signal traces transmitting different byte signals in four diagonal directions.

Similarly, for the fourth signal trace D12 on the fourth circuit layer 140, the signal traces adjacent to the fourth signal trace D12 comprise the fourth signal trace D6 and the third signal trace C1 on the third circuit layer 130, and the fourth signal trace D11 and the third signal trace C7 on the fourth circuit layer 140 (a ground trace G is arranged between the fourth signal trace D11, the third signal trace C7 and the fourth signal trace D12 to shield the signal crosstalk). In the layout of FIG. 2, the unshielded fourth signal trace D6 adjacent to the fourth signal trace D12 is configured to transmit the same byte signal, and thus the crosstalk between the fourth signal trace D6 and D12 is smaller. That is to say, in FIG. 2, other signal traces arranged in the diagonal direction (i.e., the direction between the fourth signal trace D12 and the third signal trace C1, and the direction between the fourth signal trace D12 and the fourth signal trace D6) relative to one of the fourth signal traces D1˜D12 (e.g., the fourth signal trace D12) comprise another fourth signal trace (e.g., the fourth signal trace D6) transmitting the same byte signal, rather than the signal traces transmitting different byte signals in four diagonal directions.

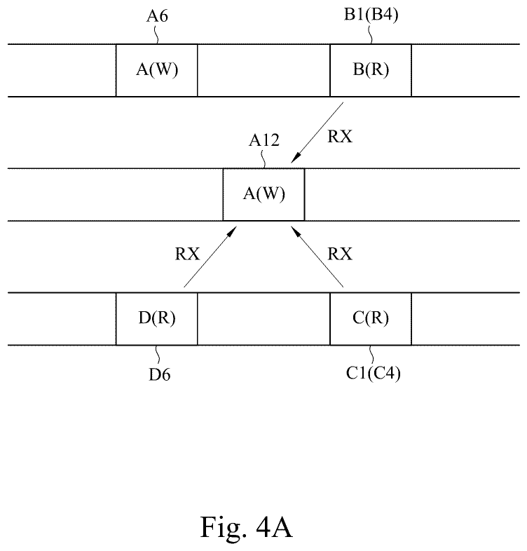

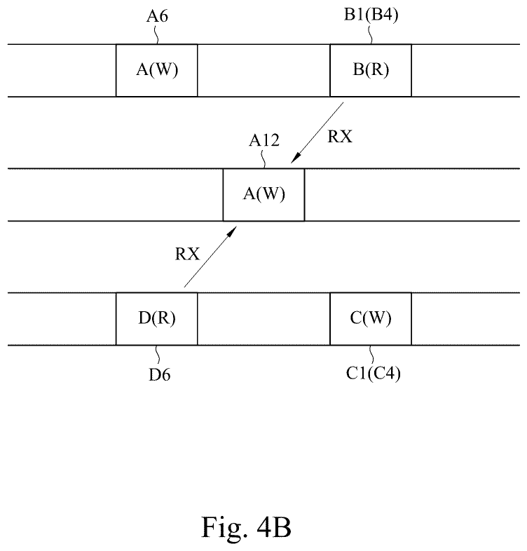

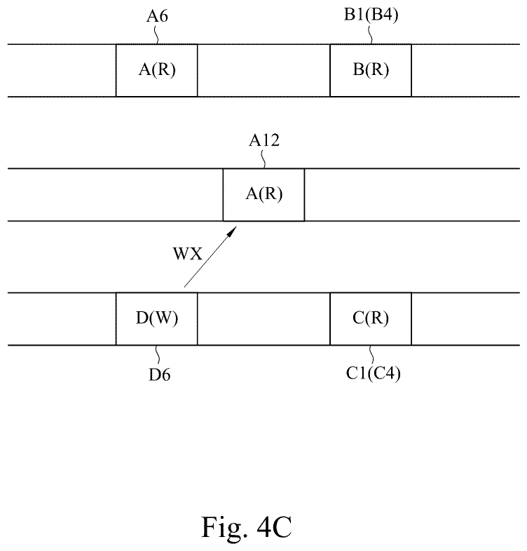

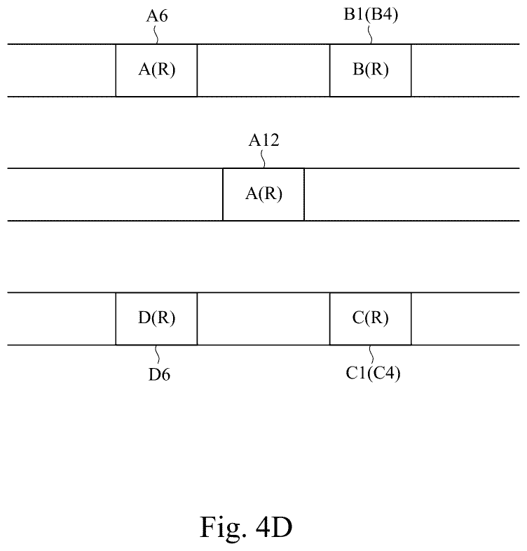

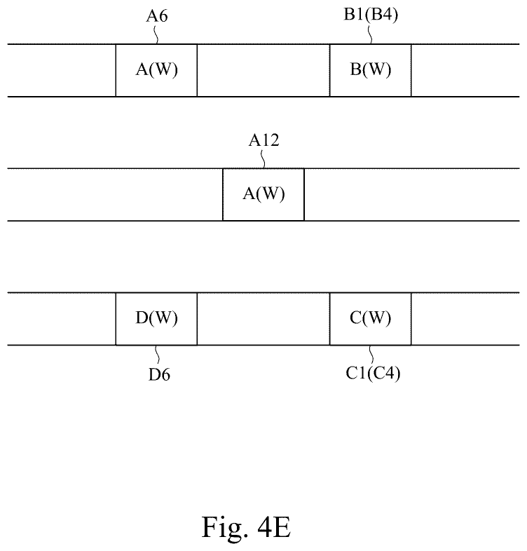

As such, by the circuit layout of the first signal traces A1˜A12, the second signal traces B1˜B12, the third signal traces C1˜C12 and the fourth signal traces D1˜D12 of the semiconductor wiring substrate 100 in FIG. 2 on the first circuit layer 110, the second circuit layer 120, the third circuit layer 130 and the fourth circuit layer 140, so that the first byte signal A and the second byte signal B can be transmitted on the adjacent first circuit layer 110 and the second circuit layer 120, and the third byte signal C and the fourth byte signal D can be transmitted on the adjacent third circuit layer 130 and the fourth circuit layer 140, resulting in reducing the crosstalk among the first signal traces A1˜A12, the second signal traces B1˜B12, the third signal traces C1˜C12 and the fourth signal traces D1˜D12 in the semiconductor wiring substrate 100. Regarding the technology where the first signal traces A1˜A12, the second signal traces B1˜B12, the third signal traces C1˜C12 and the fourth signal traces D1˜D12 are subject to the crosstalk, please refer to the description of FIGS. 4A-4E below.

In some embodiments, as shown in FIG. 2, the first dielectric layer 115 is between the first circuit layer 110 and the second circuit layer 120, the second dielectric layer 125 is between the second circuit layer 120 and the third circuit layer 130, and the third dielectric layer 135 is between the third circuit layer 130 and the fourth circuit layer 140.

In some embodiments, as shown in FIG. 2, the semiconductor wiring substrate 100 further comprises a power/ground wiring layer 150. The power/ground wiring layer 150 is arranged in parallel with the fourth circuit layer 140 (e.g., the power/ground wiring layer 150 is arranged parallel below the fourth circuit layer 140), and comprises a plurality of first power wirings 150A and a plurality of first ground wiring 150B. Specifically, the first power wirings 150A and the first ground wirings 150B are alternately arranged on the power/ground wiring layer 150 along the direction Y (i.e., the direction parallel to the power/ground wiring layer 150).

In some embodiments, as shown in FIG. 2, the semiconductor wiring substrate 100 further comprises a plurality of second power wirings 160 and a plurality of second ground wirings 170. Each of the second power wirings 160 and each of the second ground wiring 170 are respectively arranged on opposite sides of the first circuit layer 110, the second circuit layer 120, the third circuit layer 130, the fourth circuit layer 140 and the power/ground wiring layer 150, the second power wirings 160 are connected with each other by a conductive component 180, and the second ground wirings 170 are connected with each other by the conductive component 180. In some embodiments, the conductive component 180 can comprise but not be limited to a conductive via, but the present disclosure does not limit thereto.

From the above description, it can be known that the first circuit layer 110, the first dielectric layer 115, the second circuit layer 120, the second dielectric layer 125, the third circuit layer 130, the third dielectric layer 135, the fourth circuit layer 140 and the power/ground wiring layer 150 are sequentially arranged in a opposite direction of the direction Z (i.e., the arrangement direction).

It should be understood that the structure of the semiconductor wiring substrate 100 is not limited to the structure shown in FIG. 2. For example, in some embodiments, the power/ground wiring layer 150 can be arranged at other positions or omitted from the semiconductor wiring substrate 100.

Next, the relative relationship between the first circuit layer 110, the second circuit layer 120, the third circuit layer 130 and the fourth circuit layer 140 in FIG. 2 will be further described.

In some embodiments, as shown in FIG. 2, a projection 60A of one of the first signal traces A1˜A6 and the second signal traces B1˜B6 (e.g., the first signal trace A4 of FIG. 2) from the first circuit layer 110 to the second circuit layer 120 along the opposite direction of the direction Z is partially overlapped to one of the ground traces G, a projection 62A of one of the ground traces G from the first circuit layer 110 to the second circuit layer 120 along the opposite direction of the direction Z is partially overlapped to one of the first signal traces A7˜A12 and the second signal traces B7˜B12 on the second circuit layer 120 (e.g., the first signal trace A7 of FIG. 2). A projection 60B of one of the first signal traces A1˜A6 and the second signal traces B1˜B6 from the first circuit layer 110 to the third circuit layer 130 along the opposite direction of the direction Z is completely overlapped to one of the third signal traces C1˜C6 and the fourth signal traces D1˜D6 on the third circuit layer 130 (e.g., the fourth signal trace D4 of FIG. 2), a projection 62B of one of the ground traces G from the first circuit layer 110 to the third circuit layer 130 along the opposite direction of the direction Z is completely overlapped to one of the ground traces G.

In some embodiments, as shown in FIG. 2, a projection 60C of one of the first signal traces A1˜A6 and the second signal traces B1˜B6 (e.g., the first signal trace A4 of FIG. 2) from the first circuit layer 110 to the fourth circuit layer 140 along the opposite direction of the direction Z is partially overlapped to one of the ground traces G, a projection 62C of one of the ground traces G from the first circuit layer 110 to the fourth circuit layer 140 along the opposite direction of the direction Z is partially overlapped to one of the third signal traces C7˜C12 and the fourth signal traces D7˜D12 on the fourth circuit layer 140.

In other words, the first signal traces A1˜A6, the ground traces G on the second circuit layer 120, the fourth signal traces D1˜D6 and the ground traces G on the fourth circuit layer 140 are sequentially arranged along the opposite direction of the direction Z, the ground traces G on the first circuit layer 110, the first signal traces A7˜A12, the ground traces G on the third circuit layer 130 and the fourth signal traces D7˜D12 are sequentially arranged along the opposite direction of the direction Z, the second signal traces B1˜B6, the ground traces G on the second circuit layer 120, the third signal traces C1˜C6 and the ground traces on the fourth circuit layer 140 are sequentially arranged along the opposite direction of the direction Z, the ground traces G on the first circuit layer 110, the second signal traces B7˜B12, the ground traces G on the third circuit layer 130 and the third signal traces C7˜C12 are sequentially arranged along the opposite direction of the direction Z.

From the above description, it can be known that the signal traces and the ground traces on at least one circuit layer are alternately arranged with each other in both horizontal and vertical direction (i.e., the direction Y and Z).

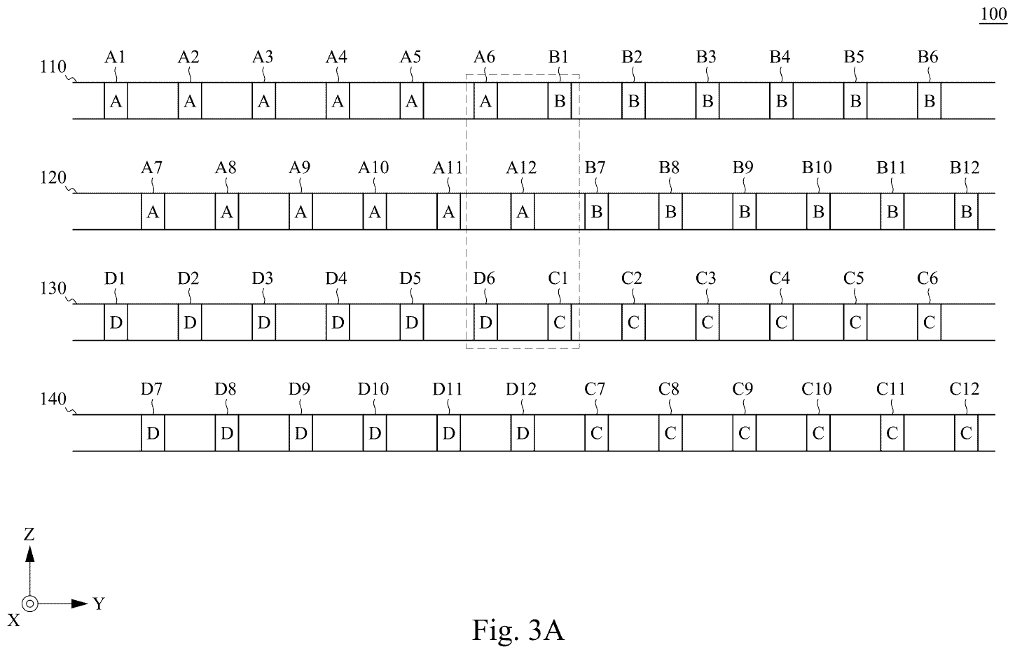

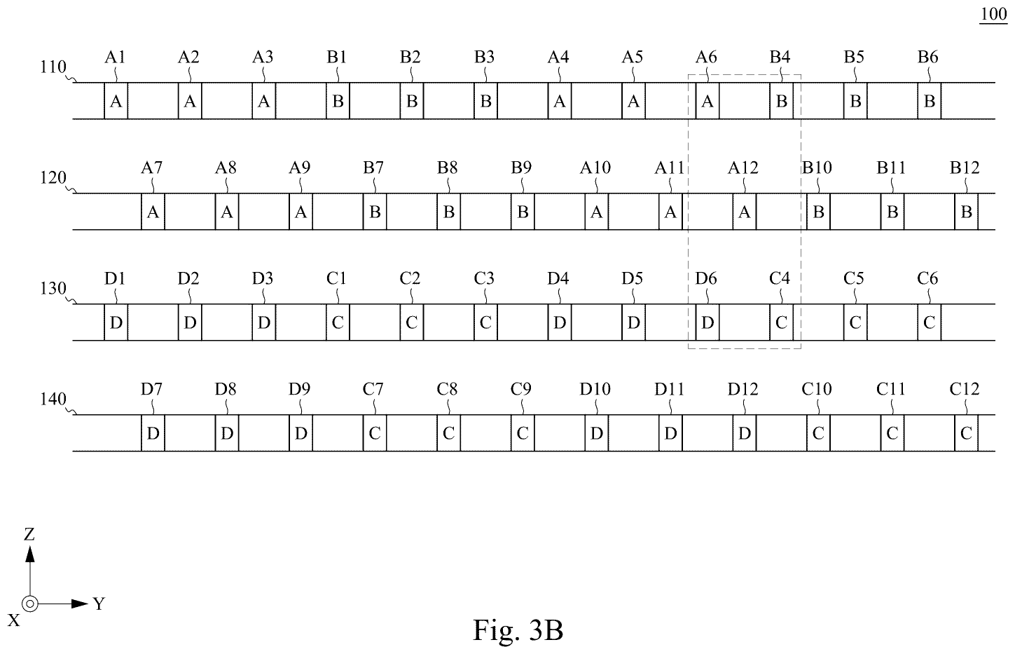

Please refer to FIG. 3A and FIG. 3B. FIG. 3A is a schematic diagram of circuit layout of one embodiment of the first signal traces A1˜A12, the second signal traces B1˜B12, the third signal traces C1˜C12 and the fourth signal traces D1˜D12 of the semiconductor wiring substrate 100 in FIG. 2. FIG. 3B is a schematic diagram of circuit layout of another embodiment of the first signal traces A1˜A12, the second signal traces B1˜B12, the third signal traces C1˜C12 and the fourth signal traces D1˜D12 of the semiconductor wiring substrate 100 in FIG. 2. For clarity and convenience of description, the semiconductor wiring substrate 100 in FIGS. 3A-3B only shows the first circuit layer 110, the second circuit layer 120, the third circuit layer 130, the fourth circuit layer 140, the first signal traces A1˜A12, the second signal traces B1˜B12, the third signal traces C1˜C12 and the fourth signal traces D1˜D12.

In some embodiments, as shown in FIG. 3A, half of the number of the first signal traces A1˜A12 (i.e., the first signal traces A1˜A6) and half of the number of the second signal traces B1˜B12 (i.e., the second signal traces B1˜B6) are sequentially arranged on the first circuit layer 110 along the direction Y (i.e., the direction parallel to the first circuit layer 110), the other half of the number of the first signal traces A1˜A12 (i.e., the first signal traces A7˜A12) and the other half of the number of the second signal traces B1˜B12 (i.e., the second signal traces B7˜B12) are sequentially arranged on the second circuit layer 120 along the direction Y (i.e., the direction parallel to the second circuit layer 120), half of the number of the fourth signal traces D1˜D12 (i.e., the fourth signal traces D1˜D6) and half of the number of the third signal traces C1˜C12 (i.e., the third signal traces C1˜C6) are sequentially arranged on the third circuit layer 130 along the direction Y (i.e., the direction parallel to the third circuit layer 130), and the other half of the number of the fourth signal traces D1˜D12 (i.e., the fourth signal traces D7˜D12) and the other half of the number of the third signal traces C1˜C12 (i.e., the third signal traces C7˜C12) are sequentially arranged on the fourth circuit layer 140 along the direction Y (i.e., the direction parallel to the fourth circuit layer 140). As such, by the circuit layout of FIG. 3A, the first byte signal A and the second byte signal B can be transmitted on the adjacent first circuit layer 110 and the second circuit layer 120, the third byte signal C and the fourth byte signal D can be transmitted on the adjacent third circuit layer 130 and the fourth circuit layer 140, resulting in reducing the crosstalk among the first signal traces A1˜A12, the second signal traces B1˜B12, the third signal traces C1˜C12 and the fourth signal traces D1˜D12 in the semiconductor wiring substrate 100. Regarding the technology where the first signal traces A1˜A12, the second signal traces B1˜B12, the third signal traces C1˜C12 and the fourth signal traces D1˜D12 are subject to the crosstalk, please refer to the description of FIGS. 4A-4E below.

In some embodiments, as shown in FIG. 3B, a first quarter of the number of the first signal traces A1˜A12 (i.e., the first signal traces A1˜A3), a first quarter of the number of the second signal traces B1˜B12 (i.e., the second signal traces B1˜B3), a second quarter of the number of the first signal traces A1˜A12 (i.e., the first signal traces A4˜A6) and a second quarter of the number of the second signal traces B1˜B12 (i.e., the second signal traces B4˜B6) are sequentially arranged on the first circuit layer 110 along the direction Y (i.e., the direction parallel to the first circuit layer 110), a third quarter of the number of the first signal traces A1˜A12 (i.e., the first signal traces A7˜A9), a third quarter of the number of the second signal traces B1˜B12 (i.e., the second signal traces B7˜B9), a fourth quarter of the number of the first signal traces A1˜A12 (i.e., the first signal traces A10˜A12) and a fourth quarter of the number of the second signal traces B1˜B12 (i.e., the second signal traces B10˜B12) are sequentially arranged on the second circuit layer 120 along the direction Y (i.e., the direction parallel to the second circuit layer 120), a first quarter of the number of the fourth signal traces D1˜D12 (i.e., the fourth signal traces D1˜D3), a first quarter of the number of the third signal traces C1˜C12 (i.e., the third signal traces C1˜C3), a second quarter of the number of the fourth signal traces D1˜D12 (i.e., the fourth signal traces D4˜D6) and a second quarter of the number of the third signal traces C1˜C12 (i.e., the third signal traces C4˜C6) are sequentially arranged on the third circuit layer 130 along the direction Y (i.e., the direction parallel to the third circuit layer 130), and a third quarter of the number of the fourth signal traces D1˜D12 (i.e., the fourth signal traces D7˜D9), a third quarter of the number of the third signal traces C1˜C12 (i.e., the third signal traces C7˜C9), a fourth quarter of the number of the fourth signal traces D1˜D12 (i.e., the fourth signal traces D10˜D12) and a fourth quarter of the number of the third signal traces C1˜C12 (i.e., the third signal traces C10˜C12) are sequentially arranged on the fourth circuit layer 140 along the direction Y (i.e., the direction parallel to the fourth circuit layer 140).

As such, by the circuit layout of FIG. 3B, the first byte signal A and the second byte signal B can also be transmitted on the adjacent first circuit layer 110 and the second circuit layer 120, the third byte signal C and the fourth byte signal D can also be transmitted on the adjacent third circuit layer 130 and the fourth circuit layer 140, resulting in reducing the crosstalk among the first signal traces A1˜A12, the second signal traces B1˜B12, the third signal traces C1˜C12 and the fourth signal traces D1˜D12 in the semiconductor wiring substrate 100. Regarding the technology where the first signal traces A1˜A12, the second signal traces B1˜B12, the third signal traces C1˜C12 and the fourth signal traces D1˜D12 are subject to the crosstalk, please refer to the description of FIGS. 4A-4E below.

Please refer to FIGS. 4A-4E. FIGS. 4A-4E are schematic diagrams of the crosstalk on the signal trace in the dotted box of FIGS. 3A-3B (e.g., the first signal trace A12 of FIG. 3A or FIG. 3B) under various operating conditions

In some embodiments, as shown in FIGS. 3A-3B and FIG. 4A, if the first signal traces A1˜A12 transmit the first byte signal A for write operation W, the second signal traces B1˜B12 transmit the second byte signal B for read operation R, the third signal traces C1˜C12 transmit the third byte signal C for the read operation R, and the fourth signal traces D1˜D12 transmit the fourth byte signal D for the read operation R, the signal trace having the most serious crosstalk among the first signal traces A1˜A12, the second signal traces B1˜B12, the third signal traces C1˜C12 and the fourth signal traces D1˜D12 (e.g., the first signal trace A12 in the dotted box of FIGS. 3A-3B or in FIG. 4A) and the first signal trace A6 in the upper left side relative to the first signal trace A12 both perform signal transmission of the write operation W. Therefore, the first signal trace A6 in the dotted box of FIGS. 3A-3B or in FIG. 4A does not cause read crosstalk to the first signal trace A12, and thus read crosstalk RX on the first signal trace A12 in FIGS. 3A-3B or in FIG. 4A is only caused by the second signal trace B1 (or B4) in the upper right side relative to the first signal trace A12, the third signal trace C1 (or C4) in the lower right side relative to the first signal trace A12 and the fourth signal trace D6 in the lower left side relative to the first signal trace A12. In other words, by the circuit layout in FIGS. 3A-3B, read crosstalk on the first signal trace A12 in FIG. 4A can be reduced by at least 25%.

In some embodiments, as shown in FIGS. 3A-3B and 4B, if the first signal traces A1˜A12 transmit the first byte signal A for the write operation W, the second signal traces B1˜B12 transmit the second byte signal B for the read operation R, the third signal traces C1˜C12 transmit the third byte signal C for the write operation W, and the fourth signal traces D1˜D12 transmit the fourth byte signal D for the read operation R, the signal trace having the most serious crosstalk among the first signal traces A1˜A12, the second signal traces B1˜B12, the third signal traces C1˜C12 and the fourth signal traces D1˜D12 (e.g., the first signal trace A12 in the dotted box of FIGS. 3A-3B or in FIG. 4B), the first signal trace A6 in the upper left side relative to the first signal trace A12 and the third signal trace C1 (or C4) in the lower right side relative to the first signal trace A12 all perform signal transmission of the write operation W. Therefore, the first signal trace A6 and the third signal trace C1 (or C4) in the dotted box of FIGS. 3A-3B or in FIG. 4B does not cause read crosstalk to the first signal trace A12, and thus read crosstalk RX on the first signal trace A12 in FIGS. 3A-3B or in FIG. 4B is only caused by the second signal trace B1 (or B4) in the upper right side relative to the first signal trace A12 and the fourth signal trace D6 in the lower left side relative to the first signal trace A12. In other words, by the circuit layout in FIGS. 3A-3B, read crosstalk on the first signal trace A12 in FIG. 4B can be reduced by at least 50%.

In some embodiments, as shown in FIGS. 3A-3B and FIG. 4C, if the first signal traces A1˜A12 transmit the first byte signal A for the read operation R, the second signal traces B1˜B12 transmit the second byte signal B for the read operation R, the third signal traces C1˜C12 transmit the third byte signal C for the read operation R, and the fourth signal traces D1˜D12 transmit the fourth byte signal D for the write operation W, the signal trace having the most serious crosstalk among the first signal traces A1˜A12, the second signal traces B1˜B12, the third signal traces C1˜C12 and the fourth signal traces D1˜D12 (e.g., the first signal trace A12 in the dotted box of FIGS. 3A-3B or in FIG. 4C), the first signal trace A6 in the upper left side relative to the first signal trace A12, the second signal trace B1 (or B4) in the upper right side relative to the first signal trace A12 and the third signal trace C1 (or C4) in the lower right side relative to the first signal trace A12 all perform signal transmission of the read operation R. Therefore, the first signal trace A6, the second signal trace B1 (or B4) and the third signal trace C1 (or C4) in the dotted box of FIGS. 3A-3B or in FIG. 4C does not cause write crosstalk to the first signal trace A12, and thus write crosstalk WX on the first signal trace A12 in FIGS. 3A-3B or in FIG. 4C is only caused by the fourth signal trace D6 in the lower left side relative to the first signal trace A12. In other words, by the circuit layout in FIGS. 3A-3B, write crosstalk on the first signal trace A12 in FIG. 4C can be reduced by at least 75%.

In some embodiments, as shown in FIGS. 3A-3B and FIG. 4D, if the first signal traces A1˜A12 transmit the first byte signal A for the read operation R, the second signal traces B1˜B12 transmit the second byte signal B for the read operation R, the third signal traces C1˜C12 transmit the third byte signal C for the read operation R, and the fourth signal traces D1˜D12 transmit the fourth byte signal D for the read operation R, the signal trace having the most serious crosstalk among the first signal traces A1˜A12, the second signal traces B1˜B12, the third signal traces C1˜C12 and the fourth signal traces D1˜D12 (e.g., the first signal trace A12 in the dotted box of FIGS. 3A-3B or in FIG. 4D), the first signal trace A6 in the upper left side relative to the first signal trace A12, the second signal trace B1 (or B4) in the upper right side relative to the first signal trace A12, the third signal trace C1 (or C4) in the lower right side relative to the first signal trace A12 and the fourth signal trace D6 in the lower left side relative to the first signal trace A12 all perform signal transmission of the read operation R. Therefore, the first signal trace A6, the second signal trace B1 (or B4), the third signal trace C1 (or C4) and the fourth signal trace D6 in the dotted box of FIGS. 3A-3B or in FIG. 4D only cause a slight read crosstalk (which is much lower than read crosstalk on the first signal trace A12 in FIGS. 4A-4B and can be ignored) to the first signal trace A12, without causing any write crosstalk. In other words, by the circuit layout in FIGS. 3A-3B, write crosstalk on the first signal trace A12 in FIG. 4D can be reduced by approximately 100%.

In some embodiments, as shown in FIGS. 3A-3B and 4E, if the first signal traces A1˜A12 transmit the first byte signal A for the write operation W, the second signal traces B1˜B12 transmit the second byte signal B for the write operation W, the third signal traces C1˜C12 transmit the third byte signal C for the write operation W, and the fourth signal traces D1˜D12 transmit the fourth byte signal D for the write operation W, the signal trace having the most serious crosstalk among the first signal traces A1˜A12, the second signal traces B1˜B12, the third signal traces C1˜C12 and the fourth signal traces D1˜D12 (e.g., the first signal trace A12 in the dotted box of FIGS. 3A-3B or in FIG. 4E), the first signal trace A6 in the upper left side relative to the first signal trace A12, the second signal trace B1 (or B4) in the upper right side relative to the first signal trace A12, the third signal trace C1 (or C4) in the lower right side relative to the first signal trace A12 and the fourth signal trace D6 in the lower left side relative to the first signal trace A12 all perform signal transmission of the write operation W. Therefore, the first signal trace A6, the second signal trace B1 (or B4), the third signal trace C1 (or C4) and the fourth signal trace D6 in the dotted box of FIGS. 3A-3B or in FIG. 4E only cause a slight write crosstalk (which is much lower than write crosstalk on the first signal trace A12 in FIG. 4C and can be ignored) to the first signal trace A12, without causing any read crosstalk. In other words, by the circuit layout in FIGS. 3A-3B, read crosstalk on the first signal trace A12 in FIG. 4E can be reduced by approximately 100%.

As such, by the circuit layout of the semiconductor wiring substrate 100 in FIGS. 3A-3B, the first signal traces A1˜A12 and the second signal traces B1˜B12 are arranged on the adjacent first circuit layer 110 and the second circuit layer 120, and the third signal traces C1˜C12 and the fourth signal traces D1˜D12 are arranged on the adjacent third circuit layer 130 and the fourth circuit layer 140, so that the first byte signal A and the second byte signal B can be transmitted on the adjacent first circuit layer 110 and the second circuit layer 120, and the third byte signal C and the fourth byte signal D can be transmitted on the adjacent third circuit layer 130 and the fourth circuit layer 140, resulting in reducing the crosstalk among the first signal traces A1˜A12, the second signal traces B1˜B12, the third signal traces C1˜C12 and the fourth signal traces D1˜D12 in the semiconductor wiring substrate 100.

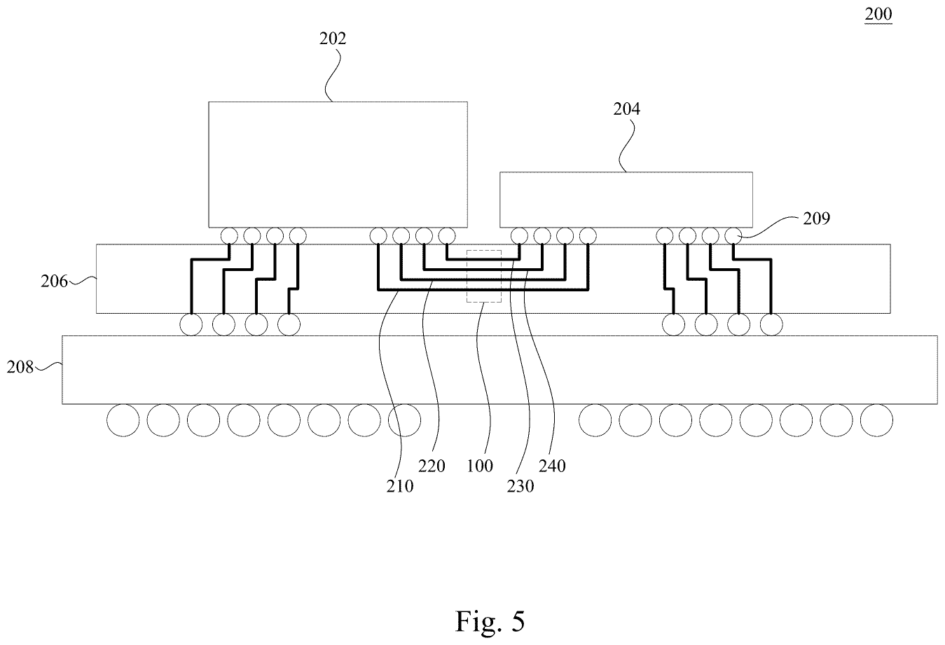

Please refer to FIG. 5. FIG. 5 is a partial schematic diagram of a semiconductor package device 200, in accordance with some embodiments of the present disclosure. In some embodiments, the semiconductor packaging device 200 comprises a first chip (i.e., a memory die) 202, a second chip (i.e., a processing chip) 204, an interposer 206 and a package substrate 208. In some embodiments, the first chip 202 can comprise but not be limited to a high bandwidth memory (HBM) or a serializer-deserializer (SerDes), the second chip 204 can comprise but not be limited to a system on a chip (SOC), the interposer 206 can comprise but not be limited to a silicon interposer with a through silicon via (TSV), and the package substrate 208 can comprise but not be limited to an integrated circuit (IC) substrate, but the present disclosure does not limit thereto.

As shown in FIG. 5, the interposer 206 comprises a first surface (e.g., an upper surface) and a second surface (e.g., a lower surface), the first chip 202 and the second chip 204 can be electrically connected to the first surface by a plurality of conductive components. 209 (e.g., solder pads, solder balls, solder bumps, etc.), and the package substrate 208 can be electrically connected to the second surface by the conductive components 209 (e.g., solder pads, solder balls, solder bumps, etc.), where the first surface and the second surface of interposer 206 are opposite to each other.

In some embodiments, the second chip 204 is electrically coupled to the first chip 202 via the interposer 206, and configured to perform a transmission of at least one signal (not shown) with the first chip 202 by at least one channel. For clarity and convenience of description, FIG. 5 only shows four channels (i.e., a first channel 210, a second channel 220, a third channel 230 and a fourth channel 240). It should be understood that number of channels is not limited to four.

In some embodiments, the interposer 206 further comprises the semiconductor wiring substrate 100 of the previous embodiment, and the semiconductor wiring substrate 100 is used for signal transmission between the first chip 202 and the second chip 204. Specifically, the first circuit layer 110 of the semiconductor wiring substrate 100 can be electrically coupled between the second chip 204 and the first chip 202 as the first channel 210, so that the second chip 204 and the first chip 202 can transmit at least one signal (e.g., the first byte signal A and the second byte signal B on the first circuit layer 110 of FIG. 3A) by the first signal traces A1˜A6 and the second signal traces B1˜B6 on the first circuit layer 110.

The second circuit layer 120 of the semiconductor wiring substrate 100 can be electrically coupled between the second chip 204 and the first chip 202 as the second channel 220, so that the second chip 204 and the first chip 202 can transmit at least one signal (e.g., the first byte signal A and the second byte signal B on the second circuit layer 120 of FIG. 3A) by the first signal traces A7˜A12 and the second signal traces B7˜B12 on the second circuit layer 120.

The third circuit layer 130 of the semiconductor wiring substrate 100 can be electrically coupled between the second chip 204 and the first chip 202 as the third channel 230, so that the second chip 204 and the first chip 202 can transmit at least one signal (e.g., the third byte signal C and the fourth byte signal D on the third circuit layer 130 of FIG. 3A) by the third signal traces C1˜C6 and the fourth signal traces D1˜D6 on the third circuit layer 130.

The fourth circuit layer 140 of the semiconductor wiring substrate 100 can be electrically coupled between the second chip 204 and the first chip 202 as the fourth channel 240, so that the second chip 204 and the first chip 202 can transmit at least one signal (e.g., the third byte signal C and the fourth byte signal D on the fourth circuit layer 140 of FIG. 3A) by the third signal traces C7˜C12 and the fourth signal traces D7˜D12 on the fourth circuit layer 140.

In some embodiments, the power/ground wiring layer 150 of the semiconductor wiring substrate 100 can be electrically coupled between the second chip 204 and the first chip 202, and configured to transmit power.

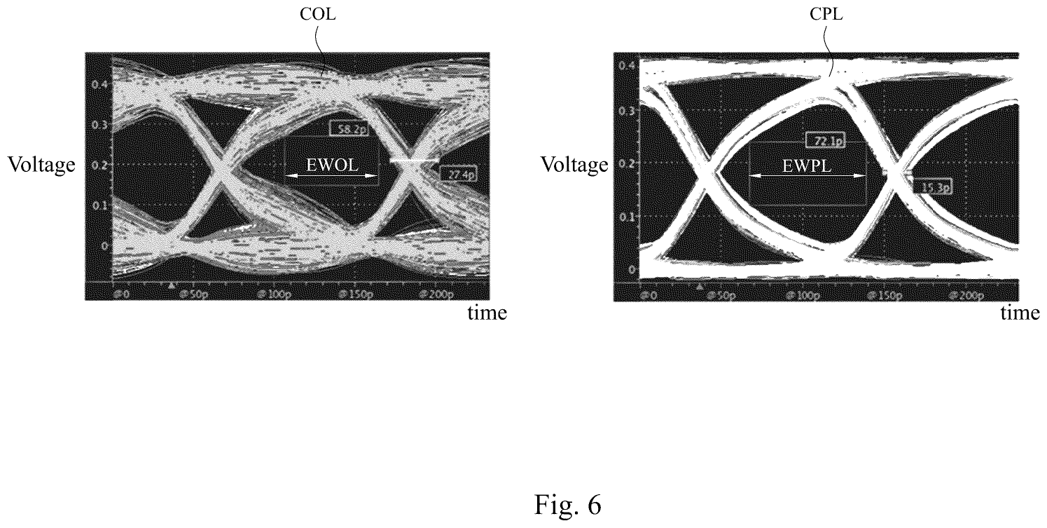

Please refer to FIG. 6. FIG. 6 is eye diagrams of signal waveforms at a relatively low transfer rate (e.g., 8.6 Gbps) for a semiconductor package device using practical application technology and the semiconductor package device 200 using the configuration of the present disclosure. As shown in FIG. 6, a curve COL presents the eye diagram of the signal waveforms at the relatively low transfer rate for the semiconductor package device using the practical application technology, and a curve CPL presents the eye diagram of the signal waveforms at the relatively low transfer rate for the semiconductor package device 200 using the configuration of the present disclosure. From FIG. 6, it can be known that the semiconductor package device 200 using the configuration of the present disclosure at the relatively low transfer rate has better eye width in comparison to the practical application technology. For example, an eye width EWPL of the curve CPL is increased by about 32.1% in comparison to an eye width EWOL of the curve COL.

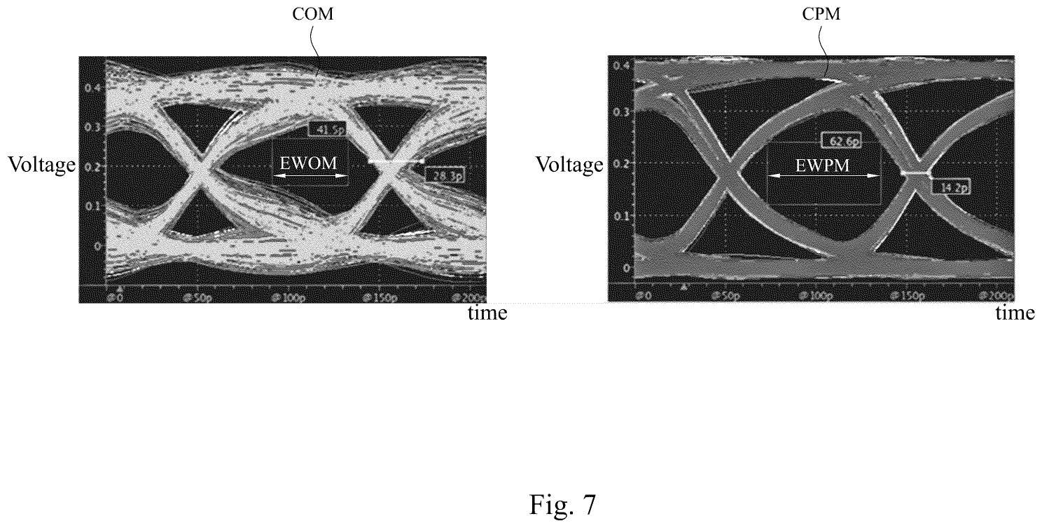

Please refer to FIG. 7. FIG. 7 is eye diagrams of signal waveforms at a medium transfer rate (e.g., 9.6 Gbps) for the semiconductor package device using practical application technology and the semiconductor package device 200 using the configuration of the present disclosure. As shown in FIG. 7, a curve COM presents the eye diagram of the signal waveforms at the medium transfer rate for the semiconductor package device using the practical application technology, and a curve CPM presents the eye diagram of the signal waveforms at the medium transfer rate for the semiconductor package device 200 using the configuration of the present disclosure. From FIG. 7, it can be known that the semiconductor package device 200 using the configuration of the present disclosure at the medium transfer rate also has better eye width in comparison to the practical application technology. For example, an eye width EWPM of the curve CPM is increased by about 43% in comparison to an eye width EWOM of the curve COM.

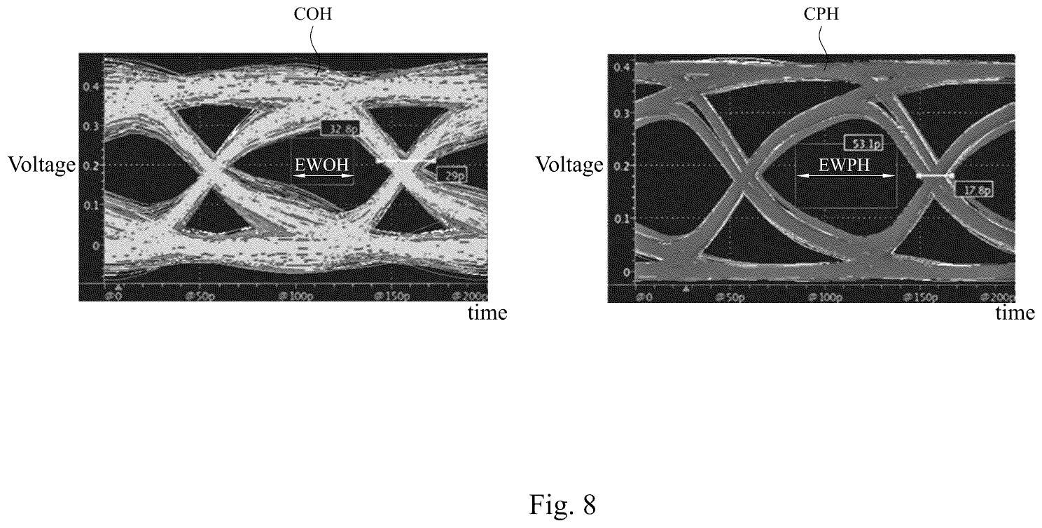

Please refer to FIG. 8. FIG. 8 is eye diagrams of signal waveforms at a relatively high transfer rate (e.g., 10 Gbps) for the semiconductor package device using practical application technology and the semiconductor package device 200 using the configuration of the present disclosure. As shown in FIG. 8, a curve COH presents the eye diagram of the signal waveforms at the relatively high transfer rate for the semiconductor package device using the practical application technology, and a curve CPH presents the eye diagram of the signal waveforms at the relatively high transfer rate for the semiconductor package device 200 using the configuration of the present disclosure. From FIG. 8, it can be known that the semiconductor package device 200 using the configuration of the present disclosure at the relatively high transfer rate also has better eye width in comparison to the practical application technology. For example, an eye width EWPH of the curve CPH is increased by about 63.7% in comparison to an eye width EWOH of the curve COH.

Therefore, from the embodiments of the present disclosure described above, it can be known that a part of the first signal traces A1˜A12 (such as the first signal traces A1˜A6) and a part of the second signal traces B1˜B12 (such as the second signal traces B1˜B6) are arranged on the first circuit layer 110, another part of the first signal traces A1˜A12 (such as the first signal traces A7˜A12) and another part of the second signal traces B1˜B12 (such as the second signal traces B7˜B12) are arranged on the second circuit layer 120 adjacent to the first circuit layer 110, so that the first byte signal A and the second byte signal B can be transmitted on the adjacent first circuit layer 110 and the second circuit layer 120 to reduce the crosstalk among the first signal traces A1˜A12 and the second signal traces B1˜B12 in the semiconductor wiring substrate 100. Furthermore, from the embodiments of the present disclosure described above, it can also be known that a part of the third signal traces C1˜C12 (such as the third signal traces C1˜C6) and a part of the fourth signal traces D1˜D12 (such as the fourth signal traces D1˜D6) are arranged on the third circuit layer 130, and another part of the third signal traces C1˜C12 (such as the third signal traces C7˜C12) and another part of the fourth signal traces D1˜D12 (such as the fourth signal traces D7˜D12) are arranged on the fourth circuit layer 140 adjacent to the third circuit layer 130, so that the third byte signal C and the fourth byte signal D can be transmitted on the adjacent third circuit layer 130 and the fourth circuit layer 140 to reduce the crosstalk among the third signal traces C1˜C12 and the fourth signal traces D1˜D12 in the semiconductor wiring substrate 100. As such, the semiconductor package device 200 and the semiconductor wiring substrate 100 thereof of the present disclosure have the advantages for increasing wiring flexibility, reducing crosstalk on the signal trace, improving signal integrity and reducing costs, etc.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A semiconductor wiring substrate, for signal transmission between a first chip and a second chip, comprising:
a first circuit layer;
a second circuit layer arranged in parallel with the first circuit layer;
a plurality of first signal traces configured to transmit a first byte signal, a part of the first signal traces is arranged on the first circuit layer, and another part of the first signal traces is arranged on the second circuit layer; and
a plurality of second signal traces configured to transmit a second byte signal, a part of the second signal traces is arranged on the first circuit layer, and another part of the second signal traces is arranged on the second circuit layer;
wherein the part of the first signal traces and the part of the second signal traces are arranged on the first circuit layer along a first direction, the another part of the first signal traces and the another part of the second signal traces are arranged on the second circuit layer along the first direction.

2. The semiconductor wiring substrate of claim 1, wherein
other signal traces arranged in a diagonal direction relative to one of the first signal traces comprise another one of the first signal traces transmitting the same byte signal,
other signal traces arranged in the diagonal direction relative to one of the second signal traces comprise another one of the second signal traces transmitting the same byte signal.

3. The semiconductor wiring substrate of claim 1, further comprising:
a third circuit layer arranged in parallel with the second circuit layer;
a fourth circuit layer arranged in parallel with the third circuit layer;
a plurality of third signal traces configured to transmit a third byte signal, a part of the third signal traces is arranged on the third circuit layer, and another part of the third signal traces is arranged on the fourth circuit layer; and
a plurality of fourth signal traces configured to transmit a fourth byte signal, a part of the fourth signal traces is arranged on the third circuit layer, and another part of the fourth signal traces is arranged on the fourth circuit layer;
wherein the part of the fourth signal traces and the part of the third signal traces are arranged on the third circuit layer along the first direction, the another part of the fourth signal traces and the another part of the third signal traces are arranged on the fourth circuit layer along the first direction.

4. The semiconductor wiring substrate of claim 3, wherein
other signal traces arranged in a diagonal direction relative to one of the first signal traces comprise another one of the first signal traces transmitting the same byte signal,
other signal traces arranged in the diagonal direction relative to one of the second signal traces comprise another one of the second signal traces transmitting the same byte signal,
other signal traces arranged in the diagonal direction relative to one of the third signal traces comprise another one of the third signal traces transmitting the same byte signal,
other signal traces arranged in the diagonal direction relative to one of the fourth signal traces comprise another one of the fourth signal traces transmitting the same byte signal.

5. The semiconductor wiring substrate of claim 1, wherein half of the first signal traces and half of the second signal traces are sequentially arranged on the first circuit layer along the first direction, and the other half of the first signal traces and the other half of the second signal traces are sequentially arranged on the second circuit layer along the first direction.

6. The semiconductor wiring substrate of claim 1, wherein a first quarter of the first signal traces, a first quarter of the second signal traces, a second quarter of the first signal traces and a second quarter of the second signal traces are sequentially arranged on the first circuit layer along the first direction, a third quarter of the first signal traces, a third quarter of the second signal traces, a fourth quarter of the first signal traces and a fourth quarter of the second signal traces are sequentially arranged on the second circuit layer along the first direction.

7. The semiconductor wiring substrate of claim 3, wherein a plurality of ground traces are further arranged on the first circuit layer, the second circuit layer, the third circuit layer and the fourth circuit layer, and each of the ground traces is respectively arranged between two adjacent signal traces.

8. The semiconductor wiring substrate of claim 3, further comprising:
a first dielectric layer, between the first circuit layer and the second circuit layer;
a second dielectric layer, between the second circuit layer and the third circuit layer; and
a third dielectric layer, between the third circuit layer and the fourth circuit layer.

9. The semiconductor wiring substrate of claim 3, further comprising:
a power/ground wiring layer arranged in parallel with the fourth circuit layer, and comprises a plurality of first power wirings and a plurality of first ground wirings, the first power wirings and the first ground wirings are alternately arranged on the power/ground wiring layer along the first direction;
a plurality of second power wirings; and
a plurality of second ground wirings, each of the second power wirings and each of the second ground wirings are respectively arranged on opposite sides of the first circuit layer, the second circuit layer, the third circuit layer, the fourth circuit layer and the power/ground wiring layer, the second power wirings are connected with each other by a conductive component, the second ground wirings are connected with each other by the conductive component, the conductive component is a conductive via.

10. The semiconductor wiring substrate of claim 7, wherein a first projection of one of the first signal traces and the second signal traces from the first circuit layer to the second circuit layer along a second direction is partially overlapped to one of the ground traces, a second projection of one of the ground traces from the first circuit layer to the second circuit layer along the second direction is partially overlapped to one of the first signal traces and the second signal traces on the second circuit layer, a third projection of one of the first signal traces and the second signal traces from the first circuit layer to the third circuit layer along the second direction is completely overlapped to one of the third signal traces and the fourth signal traces on the third circuit layer, a fourth projection of one of the ground traces from the first circuit layer to the third circuit layer along the second direction is completely overlapped to one of the ground traces, a fifth projection of one of the first signal traces and the second signal traces from the first circuit layer to the fourth circuit layer along the second direction is partially overlapped to one of the ground traces, a sixth projection of one of the ground traces from the first circuit layer to the fourth circuit layer along the second direction is partially overlapped to one of the third signal traces and the fourth signal traces on the fourth circuit layer.

11. A semiconductor package device, comprising:
a first chip;
a second chip configured to perform a transmission of at least one signal with the first chip by at least one channel;
a package substrate; and
an interposer comprising a semiconductor wiring substrate, a first surface and a second surface, wherein the second chip is electrically coupled to the first chip via the interposer, the first surface and the second surface are opposite to each other, the first chip and the second chip are electrically connected to the first surface, and the package substrate is electrically connected to the second surface;
wherein the semiconductor wiring substrate comprises:
a first circuit layer;
a second circuit layer arranged in parallel with the first circuit layer;
a plurality of first signal traces configured to transmit a first byte signal, a part of the first signal traces is arranged on the first circuit layer, and another part of the first signal traces is arranged on the second circuit layer; and
a plurality of second signal traces configured to transmit a second byte signal, a part of the second signal traces is arranged on the first circuit layer, and another part of the second signal traces is arranged on the second circuit layer; and
wherein the part of the first signal traces and the part of the second signal traces are arranged on the first circuit layer along a first direction, the another part of the first signal traces and the another part of the second signal traces are arranged on the second circuit layer along the first direction.

12. The semiconductor package device of claim 11, wherein
other signal traces arranged in a diagonal direction relative to one of the first signal traces comprise another one of the first signal traces transmitting the same byte signal,
other signal traces arranged in the diagonal direction relative to one of the second signal traces comprise another one of the second signal traces transmitting the same byte signal.

13. The semiconductor package device of claim 11, further comprising:
a third circuit layer arranged in parallel with the second circuit layer;
a fourth circuit layer arranged in parallel with the third circuit layer;
a plurality of third signal traces configured to transmit a third byte signal, a part of the third signal traces is arranged on the third circuit layer, and another part of the third signal traces is arranged on the fourth circuit layer; and
a plurality of fourth signal traces configured to transmit a fourth byte signal, a part of the fourth signal traces is arranged on the third circuit layer, and another part of the fourth signal traces is arranged on the fourth circuit layer;
wherein the part of the fourth signal traces and the part of the third signal traces are arranged on the third circuit layer along the first direction, the another part of the fourth signal traces and the another part of the third signal traces are arranged on the fourth circuit layer along the first direction.

14. The semiconductor package device of claim 13, wherein
other signal traces arranged in a diagonal direction relative to one of the first signal traces comprise another one of the first signal traces transmitting the same byte signal,
other signal traces arranged in the diagonal direction relative to one of the second signal traces comprise another one of the second signal traces transmitting the same byte signal,
other signal traces arranged in the diagonal direction relative to one of the third signal traces comprise another one of the third signal traces transmitting the same byte signal,
other signal traces arranged in the diagonal direction relative to one of the fourth signal traces comprise another one of the fourth signal traces transmitting the same byte signal.

15. The semiconductor package device of claim 11, wherein half of the first signal traces and half of the second signal traces are sequentially arranged on the first circuit layer along the first direction, and the other half of the first signal traces and the other half of the second signal traces are sequentially arranged on the second circuit layer along the first direction.

16. The semiconductor package device of claim 11, wherein a first quarter of the first signal traces, a first quarter of the second signal traces, a second quarter of the first signal traces and a second quarter of the second signal traces are sequentially arranged on the first circuit layer along the first direction, a third quarter of the first signal traces, a third quarter of the second signal traces, a fourth quarter of the first signal traces and a fourth quarter of the second signal traces are sequentially arranged on the second circuit layer along the first direction.
